(19) United States
(12) Patent Application Publication
(10) Pub. No.: US 2013/0311119 A1
(43) Pub. Date: Nov. 21, 2013

(54) METHOD OF DETECTING BATTERY FULL-CHARGE CAPACITY

(71) Applicant: Shigeto Tamezane, Hyogo (JP)

(72) Inventor: Shigeto Tamezane, Hyogo (JP)

(21) Appl. No.: 13/982,624

(22) PCT Filed: Jan. 30, 2012
(86) PCT No.: PCT/JP2012/051980

§ 371 Date: Jul. 30, 2013

(30) Foreign Application Priority Data
Jan. 31, 2011 (JP) 2011-019279

(51) Int. Cl. G01R 31/36

(52) U.S. Cl. CPC G01R 31/36
USPC 702/63

(57) ABSTRACT

A method including a remaining charge capacity determination step to determine a first remaining charge capacity from the first open circuit voltage and a second remaining charge capacity from the second open circuit voltage, a change in remaining charge capacity computation step to compute the change in remaining charge capacity from the difference between the first remaining charge capacity and the second remaining charge capacity, and a full-charge capacity computation step to compute the battery full-charge capacity from the change in remaining charge capacity and the change in charge capacity. The method computes battery full-charge capacity from the change in charge capacity and the change in remaining charge capacity when at least one of the values, namely the change in charge capacity, the change in remaining charge capacity, and the difference between the first open circuit voltage and the second open circuit voltage, is greater than a preset value.

### BACKGROUND OF THE INVENTION

1. Field of the Invention

The present invention relates to a method of detecting battery full-charge capacity for a battery with an actual full-charge capacity that decreases over time as the battery is charged and discharged.

2. Description of the Related Art

The actual full-charge capacity (Ampere-hours at full-charge, [Ahf]) to which a battery can be charged decreases over time as charging and discharging are repeatedly performed. Full-charge capacity (Ahf) is the charge capacity obtained from a fully-charged battery that is discharged to a state of complete discharge. Since batteries have the property that over-charging and over-discharging result in marked degradation, operation within a defined range of remaining charge capacity (state-of-charge, SOC [%]), which is a percent of the full-charge capacity (Ahf), can limit degradation. For this reason, accurate detection of the full-charge capacity (Ahf), which decays over time, is important to prevent over-charging and over-discharging. This is because even if charging and discharging is controlled to maintain a given remaining charge capacity (SOC [%]), which is a set ratio of the full-charge capacity (Ahf), charging and discharging can extend into regions of over-charging or over-discharging and degradation can result when there is error in the detected full-charge capacity (Ahf). For example, charging and discharging of a battery in an automotive application is controlled to maintain remaining charge capacity within a given range centered at the 50% level. Since the remaining charge capacity (SOC [%]) is based on reference to the full-charge capacity (Ahf), the remaining charge capacity (SOC [%]) cannot be controlled within a given range centered at 50% when there is error in the full-charge capacity (Ahf).

As an example, a battery with a full-charge capacity (Ahf) of 10 Ah has a remaining charge capacity (SOC [%]) of 50% when it is discharged to a capacity of 5 Ah. However, for a battery with full-charge capacity (Ahf) that has decreased to 5 Ah, the remaining charge capacity (SOC [%]) becomes 100% when the capacity is 5 Ah. Consequently, if charging and discharging is controlled to maintain a center-point of 5 Ah for a battery with full-charge capacity that has dropped in half from 10 Ah to 5 Ah, charging and discharging is actually performed with a remaining charge capacity (SOC [%]) center-point of 100% resulting in over-charging and significant degradation. Particularly for a vehicle power source apparatus, it is important to control battery remaining charge capacity (SOC [%]) within a range centered at 50% to allow both charging and discharging. This is because the vehicle is accelerated by discharging the battery and decelerated by regenerative braking that charges the battery.

Besides power source apparatus installed on-board a vehicle, other power source apparatus, such as one charged by solar cell power, employ numerous battery cells for charging with high-power. In this type of application as well, it is important to limit degradation of the many individual battery cells to extend battery lifetime. Accordingly, it is important to accurately detect battery full-charge capacity (Ahf) to prevent over-charging and over-discharging.

Battery full-charge capacity (Ahf) can be determined by integrating the charge capacity during charging to fully-charge the battery from a completely discharged state. Or, full-charge capacity (Ahf) can be determined by integrating the discharged capacity during discharge from a fully-charged state to a completely discharged state. Although these methods can accurately detect battery full-charge capacity (Ahf), they have the drawback that severe restrictions are imposed on the battery operating environment. This is because no power can be drawn from the battery when it is in a completely discharged state, and no power can be supplied to the battery when it is in a fully-charged state. For example, in a battery installed on-board a vehicle, the vehicle is accelerated via a motor by discharging the battery, and when the vehicle is decelerated due to brake application, the battery is charged with a generator via regenerative braking. Therefore, the vehicle cannot be accelerated when the battery is in a completely discharged state, and the battery cannot be charged by regenerative braking when the battery is in a fully-charged state. This situation is not limited to vehicle batteries, and not only is time required to completely discharge the battery, but this method of detecting full-charge capacity (Ahf) has the drawback that the battery is unusable in the completely discharged state. In addition, batteries have the property that they are easily degraded in operating regions corresponding to full-charge and complete discharge (over-discharge). Consequently, a method that completely discharges and fully-charges a battery to determine its full-charge capacity (Ahf) is in itself a cause of battery degradation.

To resolve these drawbacks, a method has been developed to detect the amount of decrease in full-charge capacity (Ahf) by determining the battery degradation level from the cumulative charging capacity (refer to Japanese Laid-Open Patent Publication 2002-236154). Further, Japanese Patent Publication 2002-236154 also cites a method of detecting the rate of full-charge capacity reduction using battery storage temperature and remaining charge capacity as parameters.

The method cited in Japanese Patent Publication 2002-236154 detects full-charge capacity without completely discharging or fully-charging the battery. Consequently, it can detect full-charge capacity without imposing restrictions on the battery operating environment. However, since this method estimates the degree of reduction in full-charge capacity from the cumulative charging capacity, storage temperature, and remaining charge capacity, it has the drawback that it can be difficult to consistently detect accurate full-charge capacity. This is because battery degradation varies in a complex manner due to various external conditions.

To resolve these drawbacks, the present applicant developed a method of computing battery full-charge capacity (Ahf) from the change in remaining charge capacity (δSOC [%]) and the change in charge capacity (δAh) (refer to Japanese Laid-Open Patent Publication 2008-241358). Here, the change in charge capacity (δAh) is determined by integrating the charging and discharging current of the battery being charged and discharged, battery open circuit voltage (Vocv) is detected before and after the change in charge capacity (δAh) is detected, the change in remaining charge capacity (δSOC [%]) is determined from the respective open circuit voltages (Vocv), and the battery full-charge capacity (Ahf) is determined by the following equation from the change in remaining charge capacity (δSOC [%]) and the change in charge capacity (δAh).

Full-charge capacity (Ahf)=δAh/(δSOC [%]/100%)

The method of detecting full-charge capacity described above has the characteristic that battery full-charge capacity can be determined without fully-charging or completely discharging the battery. This is because the change in battery charge capacity (δAh) is determined by integrating the charging and discharging current of the battery being charged and discharged, the change in remaining charge capacity (δSOC [%]) is determined at the same time the change in charge capacity (δAh) is detected, and battery full-charge capacity (Ahf) is computed from the change in remaining charge capacity (δSOC [%]) and the change in charge capacity (δAh).

However, it is difficult for this method to always accurately detect the battery full-charge capacity (Ahf). If the battery full-charge capacity (Ahf) is revised when it cannot be accurately detected, error in the revised full-charge capacity (Ahf) will increase. Consequently, this method has the drawback that it becomes impossible to always detect the battery full-charge capacity (Ahf) accurately.

The present invention was developed to further resolve the drawbacks described above. Thus, it is an important object of the present invention to provide a method of detecting battery full-charge capacity that can more accurately detect full-charge capacity (Ahf) without fully-charging or completely discharging the battery.

### SUMMARY OF THE INVENTION

The method of detecting full-charge capacity of the present invention has a change in charge capacity detection step to compute the change in charge capacity (δAh) from integrated values of battery charging and discharging current at designated times during battery charging and discharging;

an open circuit voltage detection step to detect a first open circuit voltage (Vocv1) and a second open circuit voltage (Vocv2) before and after the change in charge capacity (δAh) is detected;

a remaining charge capacity determination step to determine a first remaining charge capacity (SOC1 [%]) from the first open circuit voltage (Vocv1) detected in the open circuit voltage detection step and a second remaining charge capacity (SOC2 [%]) from the second open circuit voltage (Vocv2);

a change in remaining charge capacity computation step to compute the change in remaining charge capacity (δSOC [%]) from the difference between the first remaining charge capacity (SOC1 [%]) and the second remaining charge capacity (SOC2 [%]) determined in the remaining charge capacity determination step; and a full-charge capacity computation step to compute the battery full-charge capacity (Ahf) from the change in remaining charge capacity (δSOC [%]) and the change in charge capacity (δAh).

Further, the method of detecting battery full-charge capacity of the present invention computes battery full-charge capacity from the change in charge capacity (δAh) and the change in remaining charge capacity (δSOC [%]) when at least one of the values, which are the change in charge capacity (δAh), the change in remaining charge capacity (δSOC [%]), and the difference between the first open circuit voltage (Vocv1) and the second open circuit voltage (Vocv2), exceeds a preset value.

The method of detecting full-charge capacity described above has the characteristic that it can detect battery full-charge capacity (Ahf) more accurately without fully-charging or completely discharging the battery. This is because the method of detecting full-charge capacity described above computes battery full-charge capacity from the change in charge capacity (δAh) and the change in remaining charge capacity (δSOC [%]) only under the condition that at least one of the values, which are the change in charge capacity (δAh), the change in remaining charge capacity (δSOC [%]), and the difference between the first open circuit voltage (Vocv1) and the second open circuit voltage (Vocv2), is greater than a preset value.

For a method that estimates battery remaining charge capacity (SOC [%]) from open circuit voltage (Vocv), it is difficult to always determine an accurate remaining charge capacity (SOC [%]) for a given open circuit voltage (Vocv). This is because different conditions during battery charging and discharging cause differences in the relation between remaining charge capacity (SOC [%]) and open circuit voltage (Vocv). In some cases, the actual battery remaining charge capacity (SOC [%]) can be different even for the same open circuit voltage (Vocv). Accordingly, if remaining charge capacity (SOC [%]) is estimated from open circuit voltage (Vocv) and the estimated remaining charge capacity (SOC [%]) is used as one parameter for detecting full-charge capacity (Ahf), error in the remaining charge capacity (SOC [%]) versus open circuit voltage (Vocv) relation can be the cause of error in the detected full-charge capacity (Ahf). Since error in the remaining charge capacity (SOC [%]) versus open circuit voltage (Vocv) relation can cause deviation in both the positive and negative directions, error can accumulate when remaining charge capacities (SOC [%]) are subtracted to determine the change in remaining charge capacity (δSOC [%]). In particular, during charging and discharging when changes in charge capacity (δAh) and open circuit voltage (Vocv) are small, and the change in remaining charge capacity (δSOC [%]) is determined from the estimated remaining charge capacity (SOC [%]) for each open circuit voltage (Vocv), the error can become rather significant. This is because error in the remaining charge capacity (SOC [%]) estimated for each open circuit voltage (Vocv) can be in both the positive and negative directions, and those errors can add when the change in remaining charge capacity (δSOC [%]) is determined.

FIGS. 1A and 1B illustrate difference in the magnitude of the error for a small change in remaining charge capacity (δSOC [%]) and for a large change in remaining charge capacity (δSOC [%]). FIG. 1A shows conditions for a small change in remaining charge capacity (δSOC [%]), and FIG. 1B shows conditions for a large change in remaining charge capacity (δSOC [%]). This figure shows that the error ratio (amount of error relative to the amount of change) for the change in remaining charge capacity (δSOC [%]) decreases as the amount of change in remaining charge capacity (δSOC [%]) increases. As shown in FIGS. 1A and 1B, the change in remaining charge capacity (δSOC [%]) varies from a minimum value of δSOC (%) min to a maximum value δSOC (%) max, and difference between the maximum and minimum is the same in both diagrams. Consequently, the error with respect to the change in remaining charge capacity (δSOC [%]) is (δSOC [%] max−δSOC [%] min)/δSOC (%), and that error (ratio) decreases as the denominator becomes larger.

The method of detecting battery full-charge capacity described above only detects full-charge capacity (Ahf) when the error ratio for the change in remaining charge capacity (δSOC [%]) is small. Consequently, this method achieves the characteristic that full-charge capacity (Ahf) can be detected more accurately.

In the full-charge capacity computation step of the method of detecting battery full-charge capacity of the present invention, battery full-charge capacity can be computed based on the following equation.

Full-charge capacity (Ahf)=δAh/(δSOC [%]/100%)

In the method of detecting battery full-charge capacity of the present invention, the change in charge capacity (δAh) can be compared to a set value and battery full-charge capacity can be computed from the change in charge capacity (δAh) and the change in remaining charge capacity (δSOC [%]) when the change in charge capacity (δAh) is greater than the set value.

In the method of detecting battery full-charge capacity of the present invention, the change in remaining charge capacity (δSOC [%]) can be compared to a set value and battery full-charge capacity can be computed from the change in charge capacity (δAh) and the change in remaining charge capacity (δSOC [%]) when the change in remaining charge capacity (δSOC [%]) is greater than the set value.

In the method of detecting battery full-charge capacity of the present invention, the difference between the first open circuit voltage (Vocv1) and the second open circuit voltage (Vocv2) can be compared to a set value and battery full-charge capacity can be computed from the change in charge capacity (δAh) and the change in remaining charge capacity (δSOC [%]) when the difference between the first open circuit voltage (Vocv1) and the second open circuit voltage (Vocv2) is greater than the set value.

In the method of detecting battery full-charge capacity of the present invention, battery full-charge capacity (Ahf) can be determined via the following equation from the present full-charge capacity (Ahf1) detected from the current change in remaining charge capacity (δSOC [%]) and the current change in charge capacity (δAh), and from the previously detected full-charge capacity (Ahf2).

Full-charge capacity (Ahf)=first weighting factor×present full-charge capacity (Ahf1)+second weighting factor×previous full-charge capacity (Ahf2)

Here, the sum of the first and second weighting factors is one.

First weighting factor+second weighting factor=1

Since the method of detecting full-charge capacity described above determines battery full-charge capacity (Ahf) considering the previously detected full-charge capacity (Ahf2), it can detect full-charge capacity (Ahf) more accurately.

In the method of detecting battery full-charge capacity of the present invention, the first weighting factor and the second weighting factor can vary with the change in charge capacity (δAh) and the first weighting factor can increase as the change in charge capacity (δAh) increases.

In this method, as the change in charge capacity (δAh) increases and can be detected more accurately, the battery full-charge capacity (Ahf) is revised giving more weight to the presently detected full-charge capacity (Ahf1). This allows full-charge capacity (Ahf) to be determined more accurately.

In the method of detecting battery full-charge capacity of the present invention, the first weighting factor and the second weighting factor can vary with the change in remaining charge capacity (δSOC [%]) and the first weighting factor can increase as the change in remaining charge capacity (δSOC [%]) increases.

In this method, as the change in remaining charge capacity (δSOC [%]) increases and can be detected more accurately, the battery full-charge capacity (Ahf) is revised giving more weight to the presently detected full-charge capacity (Ahf1). This allows full-charge capacity (Ahf) to be determined more accurately.

In the method of detecting battery full-charge capacity of the present invention, the first weighting factor and the second weighting factor can vary with the difference between the first open circuit voltage (Vocv1) and the second open circuit voltage (Vocv2) and the first weighting factor can increase as the voltage difference increases. In this method, as the voltage difference increases and the presently detected full-charge capacity (Ahf1) can be detected more accurately, the battery full-charge capacity (Ahf) is revised giving more weight to the presently detected full-charge capacity (Ahf1). This allows full-charge capacity (Ahf) to be determined more accurately.

In the method of detecting battery full-charge capacity of the present invention, the first weighting factor and the second weighting factor can vary with the length of the time period for detecting the change in charge capacity (δAh) and the first weighting factor can increase as the time period becomes longer.

In this method, as the time period for detecting the change in charge capacity (δAh) becomes longer and the change in charge capacity (δAh) can be detected more accurately, the battery full-charge capacity (Ahf) is revised giving more weight to the presently detected full-charge capacity (Ahf1). This allows full-charge capacity (Ahf) to be determined more accurately.

In the method of detecting battery full-charge capacity of the present invention, when the change in charge capacity (δAh), the change in remaining charge capacity (δSOC [%]), and the difference between the first open circuit voltage (Vocv1) and the second open circuit voltage (Vocv2) are all less than preset values, battery temperature can be detected to compute a battery degradation level (%), and the battery full-charge capacity (Ahf) can be computed from the battery degradation level (%), the initial battery full-charge capacity (Ahf0), and the previously detected full-charge capacity (Ahf2).

A first time point and second time point for detection can be established at times when there is no battery current flow, and the detection time period between the first and second time points can be a variable time interval. The above and further objects of the present invention as well as the features thereof will become more apparent from the following detailed description to be made in conjunction with the accompanying drawings.

### BRIEF DESCRIPTION OF THE DRAWINGS

FIG. 1 is a diagram showing that the magnitude of the error (ratio) is different depending on the size of the change in remaining charge capacity (δSOC [%]);

FIG. 2 is a circuit diagram showing a power source apparatus used in the method of detecting battery full-charge capacity for one embodiment of the present invention;

FIG. 3 is a graph showing battery open circuit voltage versus remaining battery capacity characteristics;

FIG. 4 is a graph showing open circuit voltage versus charging and discharging current characteristics for a given detected battery voltage;

FIG. 5 is a diagram showing the first weighting factor and second weighting factor as a function of the change in charge capacity (δAh);

FIG. 6 is a diagram showing the first weighting factor and second weighting factor as a function of the change in remaining charge capacity (δSOC [%]);

FIG. 7 is a diagram showing the first weighting factor and second weighting factor as a function of the ratio of the open circuit voltage (Vocv) difference to the difference between the maximum and minimum voltages;

FIG. 8 is a flowchart of showing a method of detecting battery full-charge capacity for another embodiment of the present invention;

FIG. 9 is a flowchart of showing a method of detecting battery full-charge capacity for another embodiment of the present invention; and

FIG. 10 is a flowchart of showing a method of detecting battery full-charge capacity for another embodiment of the present invention.

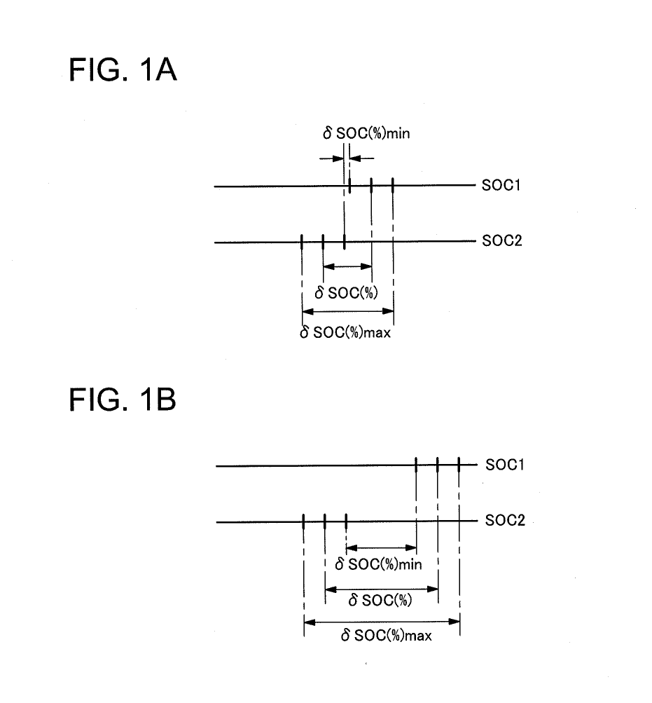

### DETAILED DESCRIPTION OF THE EMBODIMENTS

The following describes embodiments of the present invention based on the figures. However, the following embodiments are merely specific examples of a method of detecting battery full-charge capacity representative of the technology associated with the present invention, and the method of detecting full-charge capacity of the present invention is not limited to the embodiments described below. Further, components cited in the claims are in no way limited to the components indicated in the embodiments.

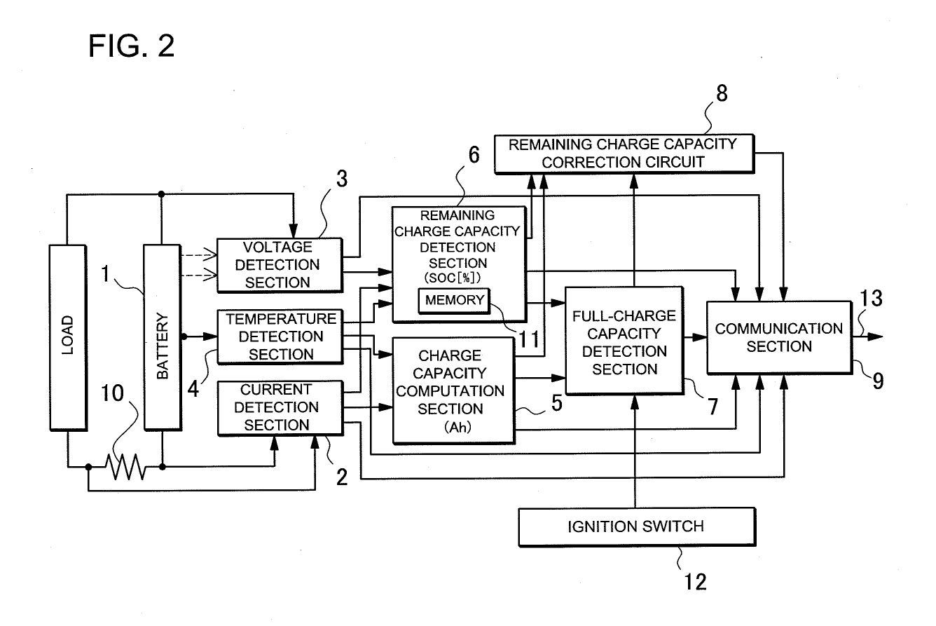

FIG. 2 is a circuit diagram of a power source apparatus used in the method of detecting battery full-charge capacity of the present invention. This power source apparatus is used to supply power to a motor and drive a vehicle, or is charged by solar cells during the daytime and used to output the stored power during either the daytime or nighttime. The power source apparatus is provided with a battery 1 that can be charged, a current detection section 2 that detects battery 1 charging and discharging current, a voltage detection section 3 that detects battery 1 voltage, a temperature detection section 4 that detects battery 1 temperature, a charge capacity computation section 5 that processes signals output from the current detection section 2 to detect battery 1 charge capacity (Ah) by integrating the charging and discharging current, a remaining charge capacity detection section 6 that determines battery 1 remaining charge capacity (SOC [%]) from signals output from the voltage detection section 3, a full-charge capacity detection section 7 that detects battery 1 full-charge capacity from signals output from the remaining charge capacity detection section 6 and the charge capacity computation section 5, a remaining charge capacity correction circuit 8 that revises battery 1 remaining charge capacity (SOC [%]) to determine an accurate remaining charge capacity (SOC [%]) based on the full-charge capacity detected by the full-charge capacity detection section 7, and a communication section 9 that transmits battery information to the vehicle-side or solar cell system-side of the equipment using the battery 1 as a power source.

The battery 1 is a lithium ion rechargeable battery or a lithium-polymer battery. However, rechargeable batteries such as nickel-hydride or nickel-cadmium batteries can be used. The battery 1 is one or a plurality of batteries connected in series or parallel.

The current detection section 2, which detects battery 1 charging and discharging current, detects the voltage induced across a current detection resistor 10 connected in series with the battery 1 to determine the charging and discharging current. The current detection section 2 amplifies the voltage induced across the current detection resistor 10 with an amplifier (not illustrated), converts the analog output of the amplifier to a digital signal via an analog-to-digital (A/D) converter, and outputs the digital signal. Since the voltage across the current detection resistor 10 is proportional to battery 1 current, the current can be detected via the voltage. The amplifier is an operational amplifier (op-amp) that can amplify both positive and negative polarities, and charging current is distinguished from discharging current by the polarity of the amplifier output. The current detection section 2 outputs current signals to the charge capacity computation section 5, the remaining charge capacity detection section 6, and the communication section 9.

The voltage detection section 3 detects battery 1 voltage, converts the detected analog voltage to a digital signal with an A/D converter (not illustrated), and outputs the digital voltage signal. The voltage detection section 3 outputs detected battery 1 voltage signals to the remaining charge capacity detection section 6 and the communication section 9. In a power source apparatus with a plurality of battery cells connected in series, voltages of the individual battery cells can be detected and an average voltage can be output. In a power source apparatus having a plurality of battery modules connected in series, where each battery module has a plurality of battery cells connected in series, an average value for the battery modules can be output as the battery voltage.

The temperature detection section 4 detects battery 1 temperature, converts the detected analog temperature to a digital signal with an ND converter (not illustrated), and outputs the digital temperature signal. The temperature detection section 4 outputs temperature signals to the charge capacity computation section 5, the remaining charge capacity detection section 6, and the communication section 9.

The charge capacity computation section 5 processes digital current signals input from the current detection section 2 to compute the charge capacity (Ah) that can be discharged by the battery 1. The charge capacity computation section 5 computes the charge capacity (Ah) that the battery 1 can discharge by integrating the current and subtracting discharging capacity from charging capacity. The charging capacity is computed by integrating the battery 1 charging current or by multiplying the integrated charging current by the charging efficiency. The discharging capacity is computed by integrating the discharging current. The charge capacity computation section 5 can temperature compensate the charging capacity and discharging capacity integrals with signals input from the temperature detection section 4 and compute accurate charge capacity.

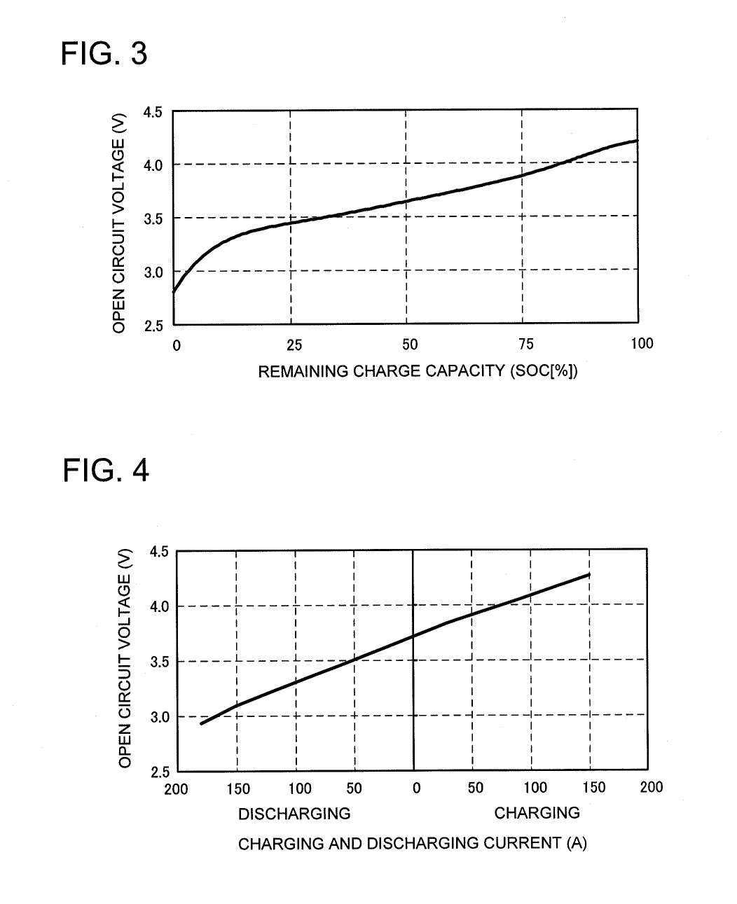

The remaining charge capacity detection section 6 determines remaining charge capacity (SOC [%]) from battery 1 open circuit voltage (Vocv). The remaining charge capacity detection section 6 detects battery 1 open circuit voltage (Vocv) from voltage signals input from the voltage detection section 3 and current signals input from the current detection section 2. Or, the remaining charge capacity detection section 6 detects the voltage input from the voltage detection section 3 as the battery 1 open circuit voltage (Vocv) when charging and discharging current input from the current detection section 2 is zero. To determine battery 1 remaining charge capacity (SOC [%]) from the open circuit voltage (Vocv), the remaining charge capacity detection section 6 stores a function or look-up-table in memory 11 that relates remaining charge capacity (SOC [%]) to the open circuit voltage (Vocv). FIG. 3 is a graph showing the relation between remaining charge capacity (SOC [%]) and battery open circuit voltage (Vocv). Memory 11 stores the remaining charge capacity versus open circuit voltage characteristics shown in the graph as a function or look-up-table. The remaining charge capacity detection section 6 determines remaining charge capacity (SOC [%]) corresponding to the open circuit voltage (Vocv) from the function or look-up-table stored in memory 11.

The remaining charge capacity detection section 6 does not necessarily have to detect open circuit voltage (Vocv) when the charging and discharging current is zero, and can also detect battery 1 open circuit voltage (Vocv) from the charging or discharging current detected by the current detection section 2. This remaining charge capacity detection section 6 has open circuit voltage (Vocv) corresponding to detected battery 1 voltage (Vccv) and charging or discharging current stored in memory 11 as a function or look-up-table. FIG. 4 is a graph showing open circuit voltage (Vocv) versus charging and discharging current for a given detected battery voltage (Vccv). Memory 11 stores the open circuit voltage versus current characteristics shown in the graph as a function or look-up-table. The remaining charge capacity detection section 6 computes the open circuit voltage (Vocv) corresponding to detected voltage and charging or discharging current from the function or look-up-table stored in memory 11, and then determines the battery 1 remaining charge capacity (SOC [%]) from the computed open circuit voltage (Vocv). This remaining charge capacity detection section 6 can detect battery 1 open circuit voltage (Vocv) regardless of whether the battery 1 is being charged or discharged, which means that the open circuit voltage (Vocv) can be detected even with charging or discharging current flow.

The charge capacity computation section 5 and remaining charge capacity detection section 6 detect battery charge capacity (Ah) and remaining charge capacity (SOC [%]) at first and second detection time points. Preferably, the first and second detection time points are at times when no battery current flows. The time interval between detection time points is longer than a preset time interval, and by establishing a detection time point after a continuous period with no battery current flow, remaining charge capacity (SOC [%]) corresponding to open circuit voltage (Vocv) can be detected more accurately. The set time interval for detection is preferably 30 min. However, the set time interval for detection can also be, for example, 1 min to 10 hrs, and preferably 10 min to 3 hrs. By lengthening the detection time interval, the remaining charge capacity (SOC [%]) corresponding to the open circuit voltage (Vocv) can be determined more accurately. By making the set time interval at the first detection time point longer than that at the second detection time point, the remaining charge capacity (SOC [%]) corresponding to the open circuit voltage (Vocv) at the first time point can be detected more accurately. By making the set time interval at the second detection time point shorter than that at the first detection time point, open circuit voltage (Vocv) and remaining charge capacity (SOC [%]) can be quickly detected after suspending charging and discharging.

However, in a method that determines remaining charge capacity (SOC [%]) by computing open circuit voltage (Vocv) from the detected voltage and the charging or discharging current, the first and second time points do not necessarily have to be at times when the battery 1 charging and discharging current is zero. Here, the detection time points can be at times when battery current is flowing.

The time interval between the first and second detection time points is not fixed at a preset time interval. By allowing the time interval to vary, the first and second time points can be established at times that are optimal for determining battery full-charge capacity (Ahf) more accurately. For example, in the case of a plug-in hybrid vehicle being charged at a charging stand, the first time point can be immediately prior to beginning charging, and the second time point can be when charging is completed. Since battery charging at a charging stand is typically performed for an extended time period, the change in charge capacity (δAh) and change in remaining charge capacity (δSOC [%]) is large and there is a high probability that battery full-charge capacity (Ahf) can be accurately detected.

In a hybrid vehicle, the first detection time point can be when the ignition switch 12 is switched ON and while battery 1 load current is cut-off. The second detection time point can be after the ignition switch 12 is switched OFF. The first time point in the hybrid vehicle can be within a given time period before and after the ignition switch 12 is switched ON. For example, the first time point can be within the period from 2 hrs prior to ignition switch 12 engagement until 3 sec after the ignition switch 12 is switched ON, and preferably until 1 sec after the ignition switch 12 is switched ON. When the first detection time point is established prior to the ignition switch 12 being switched ON, the voltage detection section 3 can use the time point of the previous battery 1 voltage detection as the first time point, and the battery voltage stored in memory 11 at that time can be used as the first open circuit voltage (Vocv1). The second detection time point can be after the ignition switch 12 is switched OFF and the battery 1 voltage stabilizes. For example, the second time point can be after the ignition switch is switched OFF and 2 hrs have elapsed.

For a battery used in a solar cell power source, the first and second detection time points can be when the battery is not being charged by the solar cells and is not being discharged to the load. However, for a battery in this type of application, the first and second time points can also be set to specified time points or can be set to establish a fixed time interval.

The charge capacity (Ah), which is the capacity that can be discharged to a state of complete discharge, and the remaining charge capacity (SOC [%]) change as the battery 1 is charged and discharged. When the battery is discharged, the charge capacity (Ah) that can be discharged to complete discharge and the remaining charge capacity (SOC [%]) decrease. When the battery is charged, the dischargeable battery charge capacity (Ah) and the remaining charge capacity (SOC [%]) increase. The dischargeable battery charge capacity (Ah), which varies between the first and second detection time points, is detected by the charge capacity computation section 5. During the time period from the first time point to the second time point, the charge capacity computation section 5 computes the change in charge capacity (δAh) by integrating battery 1 charging and discharging current, and determines the dischargeable charge capacity (Ah) from the change in charge capacity (δAh). Meanwhile, the change in remaining charge capacity (δSOC [%]), which varies between the first and second detection time points, is detected by the remaining charge capacity detection section 6. The remaining charge capacity detection section 6 detects the change in remaining charge capacity (δSOC [%]) from the difference between a first remaining charge capacity (SOC1 [%]), which is determined from the battery 1 voltage at the first time point, and a second remaining charge capacity (SOC2 [%]), which is determined from the battery 1 voltage at the second time point.

The charge capacity computation section 5 integrates battery 1 charging and discharging current in the time period from the first time point to the second time point to compute the change in charge capacity (δAh), and from the change in charge capacity (δAh) determines the varying charge capacity (Ah) that can be discharged from the battery. The remaining charge capacity detection section 6 detects the remaining charge capacity (SOC [%]) from the varying battery open circuit voltage (Vocv). The full-charge capacity detection section 7 computes the full-charge capacity (Ahf) from the change in charge capacity (δAh) and change in remaining charge capacity (δSOC [%]). To detect battery 1 change in charge capacity (δAh) and change in remaining charge capacity (δSOC [%]), the full-charge capacity detection section 7 processes change in charge capacity (δAh) and change in remaining charge capacity (δSOC [%]) for the battery 1 being charged and discharged in the period from the first time point to the second time point.

The full-charge capacity detection section 7 determines battery 1 full-charge capacity (Ahf) according to the following equation from the change in battery 1 remaining charge capacity (SOC [%]), which is the change in remaining charge capacity (δSOC [%]) detected by the remaining charge capacity detection section 6 between the first and second time points, and from the change in charge capacity (Ah) that can be discharged from the battery 1, which is the change in charge capacity (δAh) detected by the charge capacity computation section 5.

Full-charge capacity (Ahf)=δAh/(δSOC [%]/100%)

However, the full-charge capacity detection section does not always determine the full-charge capacity (Ahf) from the change in charge capacity (δAh) and the change in remaining charge capacity (δSOC [%]). The full-charge capacity detection section compares the change in charge capacity (δAh) detected in the period between the first and second time points to a set value pre-stored in memory, and only computes battery full-charge capacity from the change in charge capacity (δAh) and the change in remaining charge capacity (δSOC [%]) when the change in charge capacity (δAh) is greater than the set value. The set value stored by this full-charge capacity detection section is, for example, greater than or equal to 10% of the specified full-charge capacity (Ahf).

Instead of the change in charge capacity (δAh), the full-charge capacity detection section can also compare the change in remaining charge capacity (δSOC [%]) detected in the period between the first and second time points to a set value, and only compute battery full-charge capacity from the change in charge capacity (δAh) and the change in remaining charge capacity (δSOC [%]) when the change in remaining charge capacity (δSOC [%]) is greater than the set value. This full-charge capacity detection section has the set value of the change in remaining charge capacity (δSOC [%]) stored in memory, and the set value is, for example, greater than or equal to 10%.

Further, the full-charge capacity detection section can also compare the difference between the first open circuit voltage (Vocv1) detected at the first time point and the second open circuit voltage (Vocv2) detected at the second time point to a set value, and only compute battery full-charge capacity from the change in charge capacity (δAh) and the change in remaining charge capacity (δSOC [%]) when the voltage difference is greater than the set value. The full-charge capacity detection section stores the set value of voltage difference in memory. The set value is made greater than or equal to 20% of the difference between the maximum and minimum battery voltages.

As described above, the full-charge capacity detection section only computes battery full-charge capacity from the change in charge capacity (δAh) and the change in remaining charge capacity (δSOC [%]) between the first and second time points when at least one of the parameters, which are the change in charge capacity (δAh), the change in remaining charge capacity (δSOC [%]), and the difference between the first open circuit voltage (Vocv1) and the second open circuit voltage (Vocv2), is greater than a preset value.

The full-charge capacity detection section 7 computes the change in charge capacity (δAh) from the difference between the first charge capacity (Ah1) that the battery can discharge (detected at the first time point) and the second charge capacity (Ah2) that the battery can discharge (detected at the second time point), or from the integral of charging and discharging current in the period between the first and second time points, only when the specific conditions described above are met. In addition, the full-charge capacity detection section 7 computes the change in remaining charge capacity (δSOC [%]) from the difference between the first remaining charge capacity (SOC1 [%]) determined from the first open circuit voltage (Vocv1) detected at the first time point and the second remaining charge capacity (SOC2 [%]) determined from the second open circuit voltage (Vocv2) detected at the second time point.

The full-charge capacity detection section 7 more accurately determines battery full-charge capacity (Ahf) according to the following equation from the full-charge capacity (Ahf1) presently detected from the change in charge capacity (δAh) and the change in remaining charge capacity (δSOC [%]), and from the previously determined full-charge capacity (Ahf2).

Full-charge capacity (Ahf)=first weighting factor×present full-charge capacity (Ahf1)+second weighting factor×previous full-charge capacity (Ahf2)

Here, the sum of the first and second weighting factors is one.

First weighting factor+second weighting factor=1

The full-charge capacity detection section 7 described above does not assume the full-charge capacity (Ahf1) most recently detected from the change in charge capacity (δAh) and the change in remaining charge capacity (δSOC [%]) is the correct full-charge capacity (Ahf), but rather determines full-charge capacity (Ahf) by revising the previously detected full-charge capacity (Ahf2). In this manner, a more accurate battery full-charge capacity (Ahf) is determined.

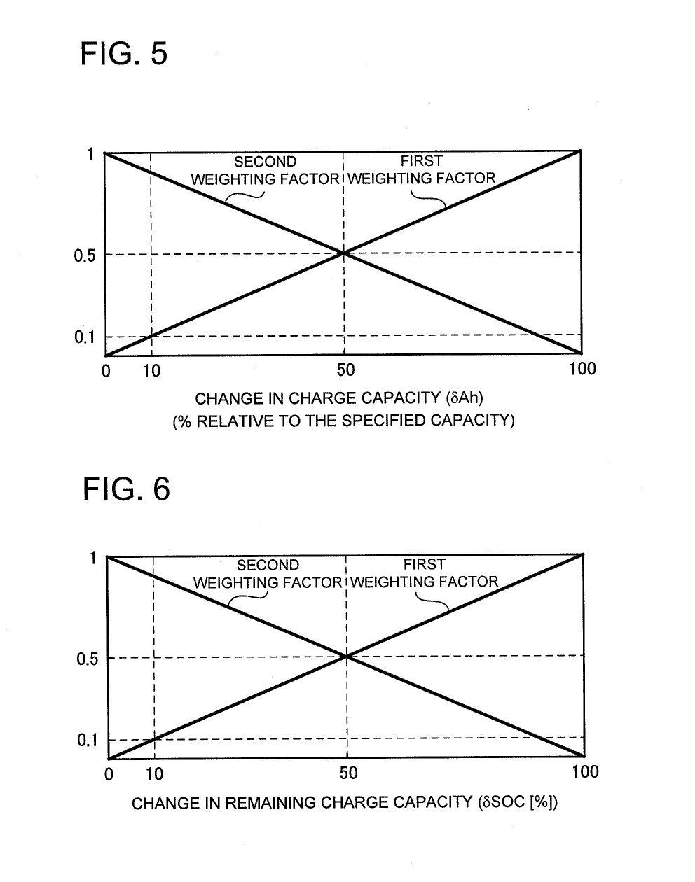

The first weighting factor is varied as a function of the change in charge capacity (δAh) within the period between the first and second detection time points. Specifically, the first weighting factor is made to increase as the change in charge capacity (δAh) increases. In this method, the first weighting factor is set to 0.1 when the change in charge capacity (δAh) is 10% of the specified charge capacity or the full-charge capacity (Ahf). As the change in charge capacity (δAh) decreases below 10%, the first weighting factor is decreased, and as the change in charge capacity (δAh) increases above 10%, the first weighting factor is increased. FIG. 5 shows the first weighting factor and second weighting factor as a function of the change in charge capacity (δAh). The relation between the first and second weighting factors and the change in charge capacity (δAh) is pre-stored in memory. In this method, the first weighting factor increases as the change in charge capacity (δAh) and the accuracy of the presently detected full-charge capacity (Ahf1) increase. This allows more accurate determination of the battery full-charge capacity (Ahf).

The first weighting factor can also be varied as a function of the change in remaining charge capacity (δSOC [%]) within the period between the first and second detection time points. The full-charge capacity detection section increases the first weighting factor as the change in remaining charge capacity (δSOC [%]) increases. For example, the first weighting factor is set to 0.1 when the change in remaining charge capacity (δSOC [%]) becomes 10%. As the change in remaining charge capacity (δSOC [%]) decreases below 10%, the first weighting factor is decreased, and as the change in remaining charge capacity (δSOC [%]) increases above 10%, the first weighting factor is increased. FIG. 6 shows the first weighting factor and second weighting factor as a function of the change in remaining charge capacity (δSOC [%]). In this method, the first weighting factor increases as the change in remaining charge capacity (δSOC [%]) and the accuracy of the presently detected full-charge capacity (Ahf1) increase. This allows more accurate determination of the battery full-charge capacity (Ahf).

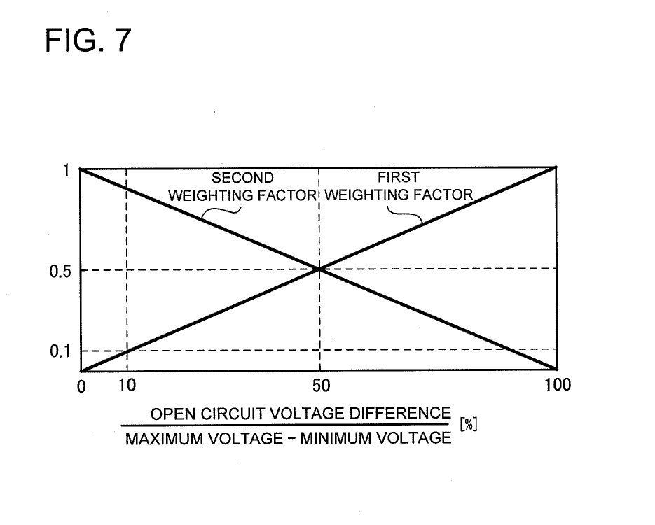

The full-charge capacity detection section can also vary the first weighting factor as a function of the difference between the first open circuit voltage (Vocv1) and the second open circuit voltage (Vocv2). This full-charge capacity detection section increases the first weighting factor as the difference between the open circuit voltages (Vocv) increases. For example, the first weighting factor is set to 0.1 when the difference between the open circuit voltages (Vocv) becomes 10% of the difference between the maximum and minimum battery voltages. As the difference between the open circuit voltages (Vocv) decreases below 10%, the first weighting factor is decreased, and as the difference between the open circuit voltages (Vocv) increases above 10%, the first weighting factor is increased. FIG. 7 shows the first weighting factor and second weighting factor as a function of the ratio of the open circuit voltage (Vocv) difference to the difference between the maximum and minimum voltages. In this method, the first weighting factor increases as the voltage difference and the accuracy of the presently detected full-charge capacity (Ahf1) increase. This allows more accurate determination of the battery full-charge capacity (Ahf).

Further, the full-charge capacity detection section can vary the first weighting factor as a function of the length of time from the first detection time point to the second detection time point. This full-charge capacity detection section increases the first weighting factor as the length of the time interval increases. For example, the first weighting factor is set to 0.1 when the time interval is 1 hr. As the length of the time interval becomes shorter than 1 hr, the first weighting factor is decreased, and as the length of the time interval becomes longer than 1 hr, the first weighting factor is increased. In this method, the first weighting factor increases as the time from the first detection time point to the second detection time point and the accuracy of the presently detected full-charge capacity (Ahf1) increase. This allows more accurate determination of the battery full-charge capacity (Ahf).

The remaining charge capacity correction circuit 8 revises battery 1 remaining charge capacity (SOC [%]) to an accurate value using the full-charge capacity (Ahf) detected by the full-charge capacity detection section 7. Specifically, remaining charge capacity (SOC [%]) is determined by the following equation from the battery 1 full-charge capacity (Ahf) detected by the full-charge capacity detection section 7, and from the charge capacity (Ah) that can be discharged by the battery 1 computed by the charge capacity computation section 5.

Remaining charge capacity (SOC [%])=(dischargeable charge capacity [Ah]/full-charge capacity [Ahf])×100%

The remaining charge capacity correction circuit 8 can accurately determine battery 1 remaining charge capacity using both the remaining charge capacity (SOC [%]) computed from the equation above and the remaining charge capacity (SOC [%]) detected from the battery voltage by the remaining charge capacity detection section 6. For example, the remaining charge capacity correction circuit 8 can compute an accurate remaining charge capacity (SOC [%]) by averaging the remaining charge capacity (SOC [%]) computed from the dischargeable charge capacity (Ah) and the full-charge capacity (Ahf), and the remaining charge capacity (SOC [%]) determined from the battery voltage. Accurate battery 1 remaining charge capacity (SOC [%]) can also be computed from a weighted calculation with the remaining charge capacity (SOC [%]) computed from the dischargeable charge capacity (Ah) and the full-charge capacity (Ahf), and the remaining charge capacity (SOC [%]) determined from the battery voltage.

The communication section 9 transmits battery information (data) to devices connected with the power source apparatus via communication lines 13. Battery data includes remaining charge capacity (SOC [%]) determined by the remaining charge capacity correction circuit 8, full-charge capacity (Ahf) detected by the full-charge capacity detection section 7, remaining charge capacity (SOC [%]) detected by the remaining charge capacity detection section 6, battery voltage detected by the voltage detection section 3, battery current detected by the current detection section 2, and battery temperature detected by the temperature detection section 4.

The power source apparatus can also determine the level of degradation of the battery 1 based on the computed full-charge capacity (Ahf). In this type of power source apparatus, battery 1 degradation level can be determined by the degree to which the computed full-charge capacity (Ahf) has decreased relative to the specified battery charge capacity (Ampere-hours-specified [Ahs]). This type of power source apparatus stores a function or look-up-table in memory that relates battery degradation level to the full-charge capacity (Ahf) or the ratio (Ahf/Ahs) of full-charge capacity (Ahf) to specified charge capacity (Ahs). The power source apparatus determines battery degradation level based on the stored function or look-up-table.

The power source apparatus described above detects battery full-charge capacity (Ahf) by the following steps.

### [Change in Charge Capacity Detection Step]

The full-charge capacity detection section 7 computes the change in battery 1 charge capacity (δAh) in the time period between the first and second detection time points from integrated values of the charging current and the discharging current of the battery 1 being charged and discharged.

In this step, the full-charge capacity detection section 7 computes the change in charge capacity (δAh) from the difference between the first charge capacity (Ah1) detected by the charge capacity computation section 5 at the first time point and the second charge capacity (Ah2) detected at the second time point. Or, the change in battery 1 charge capacity (δAh) is determined by the charge capacity computation section 5 from the integrated values of charging and discharging current in the period between the first and second time points

### [Open Circuit Voltage Detection Step]

The remaining charge capacity detection section 6 detects the first battery 1 open circuit voltage (Vocv1) at the first detection time point and the second battery 1 open circuit voltage (Vocv2) at the second detection time point. The remaining charge capacity detection section 6 detects the open circuit voltages (Vocv) at times when battery 1 charging and discharging current is zero, or computes the open circuit voltages (Vocv) from the charging and discharging currents.

### [Remaining Charge Capacity Determination Step]

The remaining charge capacity detection section 6 also determines the first remaining charge capacity (SOC1 [%]) from the first open circuit voltage (Vocv1) detected in the open circuit voltage detection step and the second remaining charge capacity (SOC2 [%]) from the second open circuit voltage (Vocv2). The remaining charge capacity detection section 6 determines remaining charge capacity (SOC [%]) from open circuit voltage (Vocv) with a function or look-up-table stored in memory 11.

### [Change in Remaining Charge Capacity Computation Step]

The full-charge capacity detection section 7 computes the change in remaining charge capacity (δSOC [%]) from the difference between the first remaining charge capacity (SOC1 [%]) and the second remaining charge capacity (SOC2 [%]) determined in the remaining charge capacity determination step.

### [Full-Charge Capacity Computation Step]

The full-charge capacity detection section 7 also determines if the change in charge capacity (δAh) between the first and second time points is greater than a set value, or if the change in remaining charge capacity (δSOC [%]) is greater than a set value, or if the difference between the first open circuit voltage (Vocv1) and the second open circuit voltage (Vocv2) is greater than a set value. The full-charge capacity detection section 7 computes battery 1 full-charge capacity (Ahf) according to the equation below from the change in charge capacity (δAh) detected in the change in charge capacity detection step and the change in remaining charge capacity (δSOC [%]) computed in the change in remaining charge capacity computation step only when either one or a plurality of the parameters, which are the change in charge capacity (δAh), the change in remaining charge capacity (δSOC [%]), and voltage difference, is/are greater than a set value.

Full-charge capacity (Ahf)=δAh/(δSOC [%]/100%)

When the change in charge capacity (δAh) between the first and second time points, the change in remaining charge capacity (δSOC [%]), and the difference between the first open circuit voltage (Vocv1) and the second open circuit voltage (Vocv2) are all less than the set values, the full-charge capacity detection section 7 computes battery 1 degradation level from the detected battery temperature and computes battery 1 full-charge capacity (Ahf) from the computed battery 1 degradation level. Battery temperature is detected by the temperature detection section 4. The full-charge capacity detection section 7 stores temperature coefficients to convert battery temperature detected by the temperature detection section 4 to battery 1 degradation level, and computes the degradation level (%) based on the temperature coefficients. Battery 1 degradation progresses with high battery temperature. Accordingly, temperature coefficients that convert battery 1 temperature to degradation level are negative coefficients with absolute values that increase with charging and discharging at high battery temperatures. These temperature coefficients are, for example, stored as a function or look-up-table.

The full-charge capacity detection section 7 detects battery temperature (for example, maximum battery temperature) with a set periodicity (for example, with a 1 sec period), and computes a degradation coefficient from the product of the temperature coefficient for the detected battery temperature and the time that the battery 1 maintained that temperature. The full-charge capacity detection section 7 adds degradation coefficients over the time from the first detection time point to the second detection time point to compute a degradation coefficient sum. The time period from the first to the second detection time points for summation of the degradation coefficient can be a set time interval such as a maximum of 4 hrs. Further, the full-charge capacity detection section 7 computes battery 1 degradation level (%) according to the following equation from the initial battery 1 full-charge capacity (Ahf0), the previous full-charge capacity (Ahf2), which is the last determined full-charge capacity (Ahf2), and the computed sum of the degradation coefficients.

Degradation level (%)=({(previous full-charge capacity [Ahf2]/initial full-charge capacity [Ahf0])×100%}²+degradation coefficient sum)^{1/2}

In addition, the full-charge capacity detection section 7 computes battery 1 full-charge capacity (Ahf) according to the following equation from the degradation level (%) computed from the battery temperature, the initial full-charge capacity (Ahf0), and the previously determined full-charge capacity (Ahf2).

Full-charge capacity (Ahf)=(previous full-charge capacity [Ahf2]×a)+(initial full-charge capacity [Ahf0]×degradation level [%]/100%)×b

Here, a and b are weighting factors determined by parameters such as battery type and operating conditions and satisfy the following equation.

a+b=1

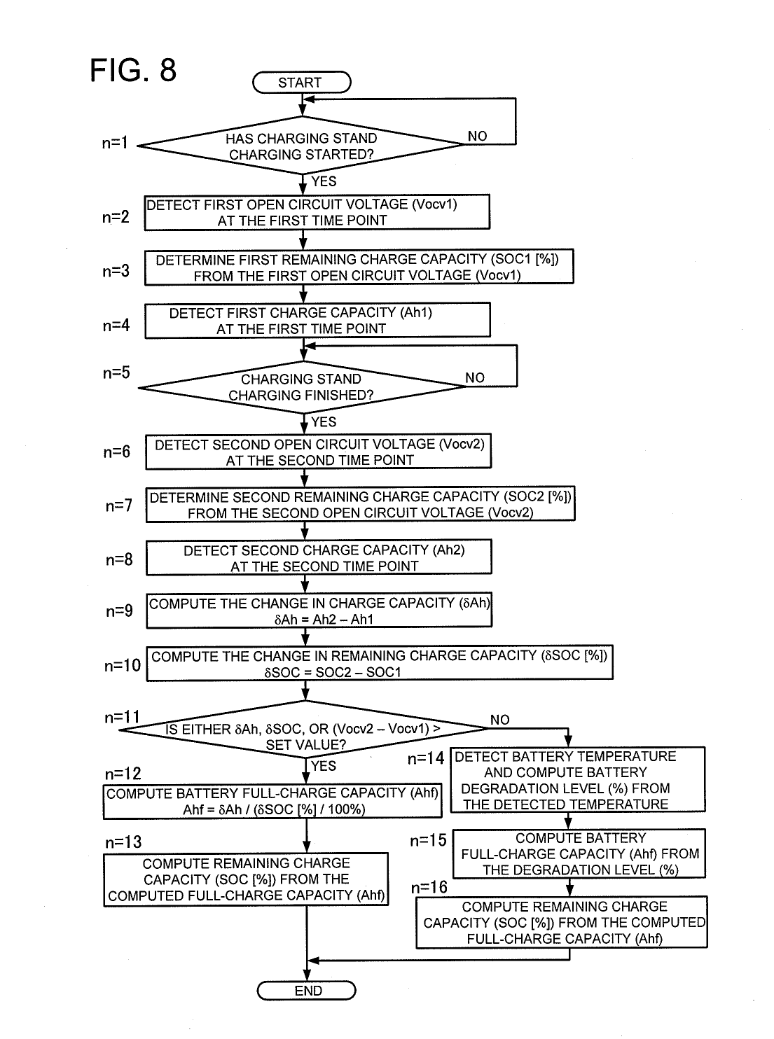

The full-charge capacity of a battery used in the power source apparatus of a plug-in hybrid vehicle is detected by the following steps in accordance with the flow-chart of FIG. 8.

[Step n=1]

Determine whether or not charging has started at a charging stand. For charging stand charging that has started, use a time prior to beginning charging with no battery current flow as the first detection time point.

[Step n=2]

The remaining charge capacity detection section 6 detects the first battery 1 open circuit voltage (Vocv1) at the first detection time point.

[Step n=3]

The remaining charge capacity detection section 6 determines the first remaining charge capacity (SOC1 [%]) from the detected first open circuit voltage (Vocv1) using a function or look-up-table.

[Step n=4]

The full-charge capacity detection section 7 detects the first battery 1 charge capacity (Ah1) at the first detection time point. For example, the full-charge capacity detection section 7 can compute the first charge capacity (Ah1) from the previously determined full-charge capacity (Ahf) with the first remaining charge capacity (SOC1 [%]) determined in step n=3.

[Step n=5]

Determine whether or not charging at the charging stand is finished. Control loops through this step until charging is complete.

[Step n=6]

When charging at the charging stand has finished, the second detection time point is established at a point following a prescribed elapsed time, and the remaining charge capacity detection section 6 detects the second open circuit voltage (Vocv2) at the second time point.

[Step n=7]

The remaining charge capacity detection section 6 determines the second remaining charge capacity (SOC2 [%]) from the detected second open circuit voltage (Vocv2) using a function or look-up-table.

[Step n=8]

The full-charge capacity detection section 7 detects the second battery 1 charge capacity (Ah2) at the second detection time point. The second battery 1 charge capacity (Ah2) is computed by the charge capacity computation section 5 by integrating battery 1 charging and discharging current.

[Step n=9]

The full-charge capacity detection section 7 computes the change in charge capacity (δAh) from the difference between the first battery 1 charge capacity (Ah1) detected at the first detection time point and the second battery 1 charge capacity (Ah2) detected at the second detection time point.

[Step n=10]

The change in remaining charge capacity (δSOC [%]) is computed from the difference between the first remaining charge capacity (SOC1 [%]) and the second remaining charge capacity (SOC2 [%]).

[Step n=11]

The full-charge capacity detection section 7 determines whether or not at least one of the parameters, which are the change in charge capacity (δAh), the change in remaining charge capacity (δSOC [%]), and the difference between the first open circuit voltage (Vocv1) and the second open circuit voltage (Vocv2), is greater than a preset value.

If any one of the parameters is greater than the set value, control proceeds to steps n=12 and 13. If all the parameters are less than or equal to the set value control proceeds to steps n=14 through 16.

[Step n=12]

The full-charge capacity detection section 7 computes battery 1 full-charge capacity (Ahf) with the following equation from the computed change in charge capacity (δAh) and change in remaining charge capacity (δSOC [%]).

Full-charge capacity (Ahf)=δAh/(δSOC [%]/100%)

[Step n=13]

The remaining charge capacity correction circuit 8 computes remaining charge capacity (SOC [%]) from the battery 1 full-charge capacity (Ahf) detected by the full-charge capacity detection section 7 and from the dischargeable charge capacity (Ah) detected by the charge capacity computation section 5. Battery 1 remaining charge capacity (SOC [%]) is determined from both the computed remaining charge capacity (SOC [%]) and the remaining charge capacity (SOC [%]) detected from the battery voltage by the remaining charge capacity detection section 6. This allows determination of a more accurate remaining charge capacity (SOC [%]).

[Step n=14]

The full-charge capacity detection section 7 computes the battery 1 degradation level (%) based on battery temperature detected by the temperature detection section 4. The full-charge capacity detection section 7 computes a degradation coefficient as the product of the temperature coefficient corresponding to the battery temperature and the time that the battery 1 maintained that temperature. Degradation coefficients are added over the interval from the first detection time point to the second detection time point to compute a degradation coefficient sum. Further, the full-charge capacity detection section 7 computes the battery 1 degradation level (%) with the following equation from the initial battery full-charge capacity (Ahf0), the previously determined full-charge capacity (Ahf2), and the degradation coefficient sum.

Degradation level (%)=({(previous full-charge capacity [Ahf2]/initial full-charge capacity [Ahf0])×100%}²+degradation coefficient sum)^{1/2}

[Step n=15]

The full-charge capacity detection section 7 computes battery 1 full-charge capacity (Ahf) with the following equation from the degradation level (%) determined from battery temperature, the initial full-charge capacity (Ahf0), and the previously determined full-charge capacity (Ahf2).

Full-charge capacity (Ahf)=(previous full-charge capacity [Ahf2]×a)+(initial full-charge capacity [Ahf0]×degradation level [%]/100%)×b

Here, a and b are weighting factors determined by parameters such as battery type and operating conditions and satisfy the following equation.

a+b=1

[Step n=16]

The remaining charge capacity correction circuit 8 computes remaining charge capacity (SOC [%]) from the battery 1 full-charge capacity (Ahf) detected by the full-charge capacity detection section 7 and from the dischargeable charge capacity (Ah) detected by the charge capacity computation section 5. Battery 1 remaining charge capacity (SOC [%]) is determined from both the computed remaining charge capacity (SOC [%]) and the remaining charge capacity (SOC [%]) detected from the battery voltage by the remaining charge capacity detection section 6. This allows determination of a more accurate remaining charge capacity (SOC [%]).

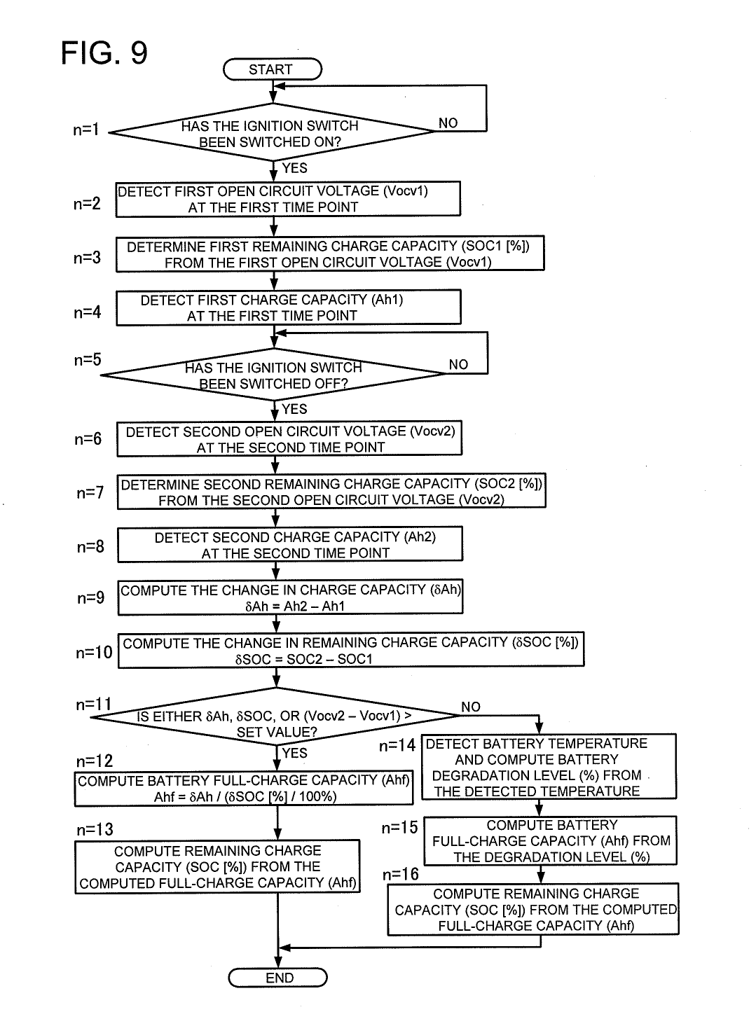

Next, the full-charge capacity of a battery used in the power source apparatus of a hybrid vehicle is detected by the following steps in accordance with the flow-chart of FIG. 9.

[Step n=1]

Determine whether or not the ignition switch 12 has been switched ON. Control loops through this step until the ignition switch 12 has been switched ON.

[Step n=2]

When the ignition switch has been switched ON, the first detection time point is established immediately after switching when battery load current is in a cut-off state. The remaining charge capacity detection section 6 detects the first battery 1 open circuit voltage (Vocv1) at the first detection time point.

[Step n=3]

The remaining charge capacity detection section 6 determines the first remaining charge capacity (SOC1 [%]) from the detected first open circuit voltage (Vocv1) using a function or look-up-table.

[Step n=4]

The full-charge capacity detection section 7 detects the first battery 1 charge capacity (Ah1) at the first detection time point. For example, the full-charge capacity detection section 7 can compute the first charge capacity (Ah1) from the previously determined full-charge capacity (Ahf) with the first remaining charge capacity (SOC1 [%]) determined in step n=3.

[Step n=5]

Determine whether or not the ignition switch 12 has been switched OFF. Control loops through this step until the ignition switch 12 has been switched OFF.

[Step n=6]

When the ignition switch has been switched OFF, the second detection time point is established at a point following a prescribed elapsed time, and the remaining charge capacity detection section 6 detects the second open circuit voltage (Vocv2) at the second time point.

[Step n=7]

The remaining charge capacity detection section 6 determines the second remaining charge capacity (SOC2 [%]) from the detected second open circuit voltage (Vocv2) using a function or look-up-table.

[Step n=8]

The full-charge capacity detection section 7 detects the second battery 1 charge capacity (Ah2) at the second detection time point. The second battery 1 charge capacity (Ah2) is computed by the charge capacity computation section 5 by integrating battery 1 charging and discharging current.

[Step n=9]

The full-charge capacity detection section 7 computes the change in charge capacity (δAh) from the difference between the first battery 1 charge capacity (Ah1) detected at the first detection time point and the second battery 1 charge capacity (Ah2) detected at the second detection time point.

[Step n=10]

The full-charge capacity detection section 7 computes the change in remaining charge capacity (δSOC [%]) from the difference between the first remaining charge capacity (SOC1 [%]) and the second remaining charge capacity (SOC2 [%]).

[Step n=11]

The full-charge capacity detection section 7 determines whether or not at least one of the parameters, which are the change in charge capacity (δAh), the change in remaining charge capacity (δSOC [%]), and the difference between the first open circuit voltage (Vocv1) and the second open circuit voltage (Vocv2), is greater than a preset value.

If any one of the parameters is greater than the set value, control proceeds to steps n=12 and 13. If all the parameters are less than or equal to the set value control proceeds to steps n=14 through 16.

[Step n=12]

The full-charge capacity detection section 7 computes battery 1 full-charge capacity (Ahf) with the following equation from the computed change in charge capacity (δAh) and change in remaining charge capacity (δSOC [%]).

Full-charge capacity (Ahf)=δAh/(δSOC [%]/100%)

[Step n=13]

The remaining charge capacity correction circuit 8 computes remaining charge capacity (SOC [%]) from the battery 1 full-charge capacity (Ahf) detected by the full-charge capacity detection section 7 and from the dischargeable charge capacity (Ah) detected by the charge capacity computation section 5. Battery 1 remaining charge capacity (SOC [%]) is determined from both the computed remaining charge capacity (SOC [%]) and the remaining charge capacity (SOC [%]) detected from the battery voltage by the remaining charge capacity detection section 6. This allows determination of a more accurate remaining charge capacity (SOC [%]).

[Step n=14]

The full-charge capacity detection section 7 computes the battery 1 degradation level (%) based on battery temperature detected by the temperature detection section 4. The full-charge capacity detection section 7 computes a degradation coefficient as the product of the temperature coefficient corresponding to the battery temperature and the time that the battery 1 maintained that temperature. Degradation coefficients are added over the interval from the first detection time point to the second detection time point to compute a degradation coefficient sum. Further, the full-charge capacity detection section 7 computes the battery 1 degradation level (%) with the following equation from the initial battery full-charge capacity (Ahf0), the previously determined full-charge capacity (Ahf2), and the degradation coefficient sum.

Degradation level (%)=({(previous full-charge capacity [Ahf2]/initial full-charge capacity [Ahf0])×100%}²+degradation coefficient sum)^{1/2}

[Step n=15]

The full-charge capacity detection section 7 computes battery 1 full-charge capacity (Ahf) with the following equation from the degradation level (%) determined from battery temperature, the initial full-charge capacity (Ahf0), and the previously determined full-charge capacity (Ahf2).

Full-charge capacity (Ahf)=(previous full-charge capacity [Ahf2]×a)+(initial full-charge capacity [Ahf0]×degradation level [%]/100%)×b

Here, a and b are weighting factors determined by parameters such as battery type and operating conditions and satisfy the following equation.

a+b=1

[Step n=16]

The remaining charge capacity correction circuit 8 computes remaining charge capacity (SOC [%]) from the battery 1 full-charge capacity (Ahf) detected by the full-charge capacity detection section 7 and from the dischargeable charge capacity (Ah) detected by the charge capacity computation section 5. Battery 1 remaining charge capacity (SOC [%]) is determined from both the computed remaining charge capacity (SOC [%]) and the remaining charge capacity (SOC [%]) detected from the battery voltage by the remaining charge capacity detection section 6. This allows determination of a more accurate remaining charge capacity (SOC [%]).

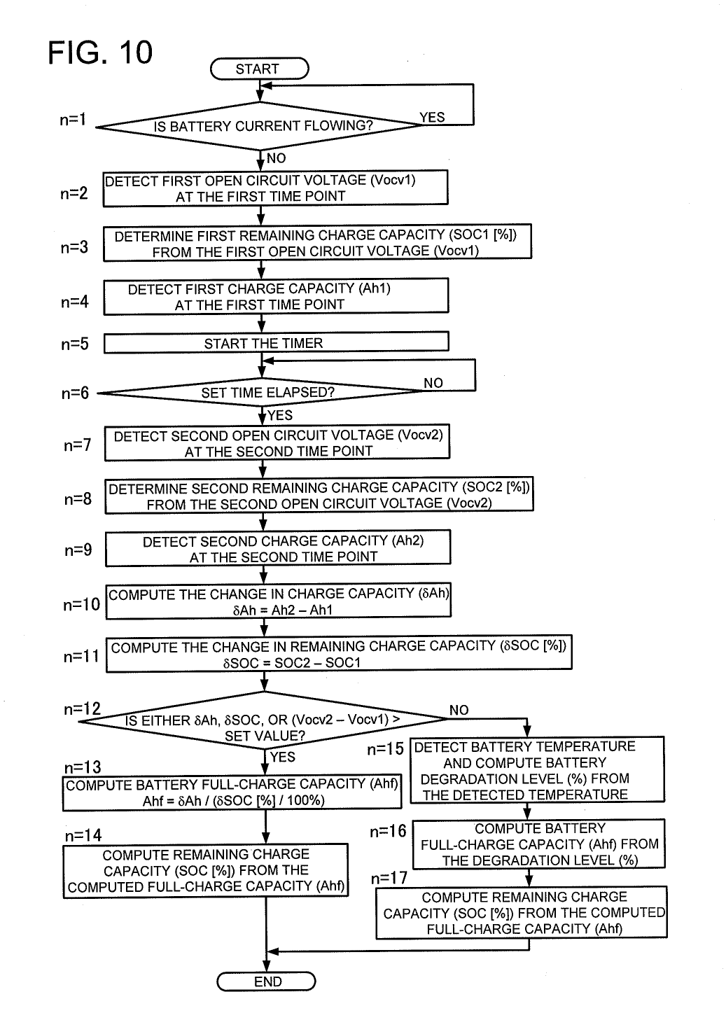

Finally, the full-charge capacity of a battery used in a solar cell power source apparatus can also be detected by the following steps shown in the flow-chart of FIG. 10.

[Steps n=1 and 2]

The first detection time point is established at a time when no battery 1 current is detected. For example, no battery 1 current flows when the solar cells are not charging the battery and the battery is not being discharged. The remaining charge capacity detection section 6 detects the first open circuit voltage (Vocv1) at the first detection time point.

[Step n=3]

The remaining charge capacity detection section 6 determines the first remaining charge capacity (SOC1 [%]) from the detected first open circuit voltage (Vocv1) using a function or look-up-table.

[Step n=4]

The full-charge capacity detection section 7 detects the first battery 1 charge capacity (Ah1) at the first detection time point. The first battery 1 charge capacity (Ah1) is computed with the charge capacity computation section 5 by integrating battery 1 charging and discharging current.

[Steps n=5 and 6]

A timer (not illustrated) is started at the first detection time point. The timer stores a set time from the first detection time point to the second detection time point and timer counting proceeds until that set time has elapsed.

[Step n=7]

When timing by the timer has elapsed, the second detection time point is established at that time. The remaining charge capacity detection section 6 detects the second open circuit voltage (Vocv2) at the second detection time point. The second open circuit voltage (Vocv2) is the detected battery 1 voltage when there is no current flow, and is computed from the detected voltage and current when there is current flow.

[Step n=8]

The remaining charge capacity detection section 6 determines the second remaining charge capacity (SOC2 [%]) from the detected second open circuit voltage (Vocv2) using a function or look-up-table.

[Step n=9]

The full-charge capacity detection section 7 detects the second battery 1 charge capacity (Ah2) at the second detection time point. The second battery 1 charge capacity (Ah2) is computed by the charge capacity computation section 5 by integrating battery 1 charging and discharging current.

[Step n=10]

The full-charge capacity detection section 7 computes the change in charge capacity (δAh) from the difference between the first battery 1 charge capacity (Ah1) detected at the first detection time point and the second battery 1 charge capacity (Ah2) detected at the second detection time point.

[Step n=11]

The full-charge capacity detection section 7 computes the change in remaining charge capacity (δSOC [%]) from the difference between the first remaining charge capacity (SOC1 [%]) and the second remaining charge capacity (SOC2 [%]).

[Step n=12]

The full-charge capacity detection section 7 determines whether or not at least one of the parameters, which are the change in charge capacity (δAh), the change in remaining charge capacity (δSOC [%]), and the difference between the first open circuit voltage (Vocv1) and the second open circuit voltage (Vocv2), is greater than a preset value.

If any one of the parameters is greater than the set value, control proceeds to steps n=13 and 14. If all the parameters are less than or equal to the set value control proceeds to steps n=15 through 17.

[Step n=13]

The full-charge capacity detection section 7 computes battery 1 full-charge capacity (Ahf) with the following equation from the computed change in charge capacity (δAh) and change in remaining charge capacity (δSOC [%]).

Full-charge capacity (Ahf)=δAh/(δSOC [%]/100%)

[Step n=14]

The remaining charge capacity correction circuit 8 computes remaining charge capacity (SOC [%]) from the battery 1 full-charge capacity (Ahf) detected by the full-charge capacity detection section 7 and from the dischargeable charge capacity (Ah) detected by the charge capacity computation section 5. Battery 1 remaining charge capacity (SOC [%]) is determined from both the computed remaining charge capacity (SOC [%]) and the remaining charge capacity (SOC [%]) detected from the battery voltage by the remaining charge capacity detection section 6. This allows determination of a more accurate remaining charge capacity (SOC [%]).

[Step n=15]

The full-charge capacity detection section 7 computes the battery 1 degradation level (%) based on battery temperature detected by the temperature detection section 4. The full-charge capacity detection section 7 computes a degradation coefficient as the product of the temperature coefficient corresponding to the battery temperature and the time that the battery 1 maintained that temperature. Degradation coefficients are added over the interval from the first detection time point to the second detection time point to compute a degradation coefficient sum. Further, the full-charge capacity detection section 7 computes the battery 1 degradation level (%) with the following equation from the initial battery full-charge capacity (Ahf0), the previously determined full-charge capacity (Ahf2), and the degradation coefficient sum.

Degradation level (%)=({(previous full-charge capacity [Ahf2]/initial full-charge capacity [Ahf0])×100%}²+degradation coefficient sum)^{1/2}

[Step n=16]

The full-charge capacity detection section 7 computes battery 1 full-charge capacity (Ahf) with the following equation from the degradation level (%) determined from battery temperature, the initial full-charge capacity (Ahf0), and the previously determined full-charge capacity (Ahf2).

Full-charge capacity (Ahf)=(previous full-charge capacity [Ahf2]×a)+(initial full-charge capacity [Ahf0]×degradation level [%]/100%)×b

Here, a and b are weighting factors determined by parameters such as battery type and operating conditions and satisfy the following equation.

a+b=1

[Step n=17]

The remaining charge capacity correction circuit 8 computes remaining charge capacity (SOC [%]) from the battery 1 full-charge capacity (Ahf) detected by the full-charge capacity detection section 7 and from the dischargeable charge capacity (Ah) detected by the charge capacity computation section 5. Battery 1 remaining charge capacity (SOC [%]) is determined from both the computed remaining charge capacity (SOC [%]) and the remaining charge capacity (SOC [%]) detected from the battery voltage by the remaining charge capacity detection section 6. This allows determination of a more accurate remaining charge capacity (SOC [%]).

1. A Method of detecting battery full-charge capacity comprising:
a change in charge capacity detection step to compute the change in charge capacity (δAh) of a battery being charged and discharged by integrating charging and discharging currents over a designated time;
an open circuit voltage detection step to detect a first open circuit voltage (Vocv1) and a second open circuit voltage (Vocv2) at times before and after the change in charge capacity (δAh) is detected;
a remaining charge capacity determination step to determine a first remaining charge capacity (SOC1 [%]) from the first open circuit voltage (Vocv1) detected in the open circuit voltage detection step and a second remaining charge capacity (SOC2 [%]) from the second open circuit voltage (Vocv2);
a change in remaining charge capacity computation step to compute the change in remaining charge capacity (δSOC [%]) from the difference between the first remaining charge capacity (SOC1 [%]) and the second remaining charge capacity (SOC2 [%]) determined in the remaining charge capacity determination step; and
a full-charge capacity computation step to compute the battery full-charge capacity (Ahf) from the change in remaining charge capacity (δSOC [%]) and the change in charge capacity (δAh),
wherein battery full-charge capacity (Ahf) is computed from the change in charge capacity (δAh) and the change in remaining charge capacity (δSOC [%]) when at least one of the values, which are the change in charge capacity (δAh), the change in remaining charge capacity (δSOC [%]), and the difference between the first open circuit voltage (Vocv1) and the second open circuit voltage (Vocv2), is greater than a preset value.

2. The method of detecting battery full-charge capacity as cited in claim 1 wherein battery full-charge capacity (Ahf) is computed based on the following equation.
Full-charge capacity (Ahf)=δAh/(δSOC [%]/100%)

3. The method of detecting battery full-charge capacity as cited in claim 1 wherein the change in charge capacity (δAh) is compared to a set value,
and battery full-charge capacity (Ahf) is computed from the change in charge capacity (δAh) and the change in remaining charge capacity (δSOC [%]) when the change in charge capacity (δAh) is greater than the set value.

4. The method of detecting battery full-charge capacity as cited in claim 1 wherein the change in remaining charge capacity (δSOC [%]) is compared to a set value,
and battery full-charge capacity (Ahf) is computed from the change in charge capacity (δAh) and the change in remaining charge capacity (δSOC [%]) when the change in remaining charge capacity (δSOC [%]) is greater than the set value.

5. The method of detecting battery full-charge capacity as cited in claim 1 wherein the difference between the first open circuit voltage (Vocv1) and the second open circuit voltage (Vocv2) is compared to a set value,
and battery full-charge capacity (Ahf) is computed from the change in charge capacity (δAh) and the change in remaining charge capacity (δSOC [%]) when the difference between the first open circuit voltage (Vocv1) and the second open circuit voltage (Vocv2) is greater than the set value.

6. The method of detecting battery full-charge capacity as cited in claim 1 wherein battery full-charge capacity (Ahf) is computed with the following equation from the present full-charge capacity (Ahf1) detected from the change in remaining charge capacity (δSOC [%]) and the change in charge capacity (δAh), and from the previously detected full-charge capacity (Ahf2).
Full-charge capacity (Ahf)=first weighting factor×present full-charge capacity (Ahf1)+second weighting factor×previous full-charge capacity (Ahf2)
Where; first weighting factor+the second weighting factor=1

7. The method of detecting battery full-charge capacity as cited in claim 6 wherein the first weighting factor and the second weighting factor vary with the change in charge capacity (δAh) and the first weighting factor increases as the change in charge capacity (δAh) increases.

8. The method of detecting battery full-charge capacity as cited in claim 6 wherein the first weighting factor and the second weighting factor vary with the change in remaining charge capacity (δSOC [%]) and the first weighting factor increases as the change in remaining charge capacity (δSOC [%]) increases.

9. The method of detecting battery full-charge capacity as cited in claim 6 wherein the first weighting factor and the second weighting factor vary with the difference between the first open circuit voltage (Vocv1) and the second open circuit voltage (Vocv2) and the first weighting factor increases as the voltage difference increases.

10. The method of detecting battery full-charge capacity as cited in claim 6 wherein the first weighting factor and the second weighting factor vary with the length of the time period for detecting the change in charge capacity (δAh) and the first weighting factor increases as the time period becomes longer.

11. The method of detecting battery full-charge capacity as cited in claim 1 wherein when the change in charge capacity (δAh), the change in remaining charge capacity (δSOC [%]), and the difference between the first open circuit voltage (Vocv1) and the second open circuit voltage (Vocv2) are all less than or equal to preset values,
battery temperature is detected to compute battery degradation level (%), and the battery full-charge capacity (Ahf) is computed from the battery degradation level (%), the initial battery full-charge capacity (Ahf0), and the previously detected full-charge capacity (Ahf2).

12. The method of detecting battery full-charge capacity as cited in claim 1 wherein the first detection time point and second detection time point are established at times when there is no battery current flow.

13. The method of detecting battery full-charge capacity as cited in claim 1 wherein the time between the first and second detection time points is a variable time interval.
